(19) United States
(12) Patent Application Publication
(10) Pub. No.: US 2008/0106882 A1
(43) Pub. Date: May 8, 2008

(54) Wireless Network Card Covering Structure

(75) Inventor: Gary Hsu, Linkou Township (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: Bandrich Inc., Sindian City (TW)

(21) Appl. No.: 11/849,706

(22) Filed: Sep. 4, 2007

(30) Foreign Application Priority Data
Oct. 23, 2006 (TW) 95218705

(51) Int. Cl. H05K 5/03

(52) U.S. Cl. 361/814

(57) ABSTRACT

A wireless network card covering structure to couple an upper metal cover and a lower metal cover of a wireless network card is disclosed. The wireless network card covering structure includes a contact structure and a coupling structure. The contact structure includes an upper metal cover wall and a lower metal cover wall. The upper metal cover wall touches the lower metal cover wall to maintain an electromagnetic susceptibility (EMS) of the wireless network card. The coupling structure includes several openings disposed on the upper metal cover wall and several plastic protrusions disposed on the lower metal cover wall. The openings would couple with the plastic protrusions to couple the upper metal cover and the lower metal cover.

### RELATED APPLICATIONS

This application claims priority to Taiwan Application Serial Number 95218705, filed Oct. 23, 2006, which is herein incorporated by reference.

### BACKGROUND

1. Field of Invention

The present invention relates to a wireless network card. More particularly, the present invention relates to a wireless network card covering structure.

2. Description of Related Art

Recently, with the progress of Internet and the popularization of personal computers, the data from different places can be communicated. However, most of the internet infrastructures are built by wires made of different materials, such as optical fibers, cables or CAT-5 patch cores, etc. However, the larger the Internet layout is, the more difficult the internet maintenance is. Thus, by utilizing wireless network card, the aforementioned problems can be resolved, and a convenient communications environment can be provided.

To provide better electromagnetic susceptibility and circuit protection in a wireless network card, the wireless network card is combined with an upper metal cover and a lower metal cover. Several metal hooks disposed between the upper metal cover and the lower metal cover may couple the upper metal cover and the lower metal cover.

However, the assembly steps using the metal hooks are quiet complicated and increase the assembly time. Also the precision required in the manufacturing of the metal hooks is highly demanding and therefore reduces the yield of the wireless network card assembly.

For the forgoing reasons, there is a need to reduce the complicated wireless network card assembly and increase the yield of wireless network card assembly.

### SUMMARY

As embodied and broadly described herein, the invention provides a wireless network card covering structure for coupling an upper metal cover and a lower metal cover. The wireless network card covering structure includes a contact structure and a coupling structure. The contact structure includes a plurality of upper metal cover walls disposed on the upper metal cover and a plurality of lower metal cover walls disposed on the lower metal cover. The upper metal cover walls touch the lower metal cover walls to maintain an electromagnetic susceptibility of the wireless network card. The coupling structure includes a plurality of openings and a plurality of plastic protrusions. The openings and the protrusions are disposed on the upper metal cover walls and the lower metal cover walls respectively. The plastic protrusions are coupled with the openings for coupling the upper metal cover and the lower metal cover.

The invention also provides a wireless network card structure. The wireless network card includes a lower metal cover and an upper metal cover. The lower metal cover includes a plurality of lower metal cover walls and a plurality of plastic protrusions disposed on the lower metal cover walls. The upper metal cover includes a plurality of upper metal cover walls and a plurality of openings disposed on the upper metal cover walls and corresponding to the plastic protrusions. The upper metal cover walls are in contact with the lower metal cover walls and the openings are coupled with the plastic protrusions to couple the upper metal cover and the lower metal cover.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is an explosion diagram of an embodiment of a wireless network card using a wireless network card covering structure of the invention; and

FIG. 2 is a sectional diagram of the embodiment of the wireless network card in FIG. 1.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

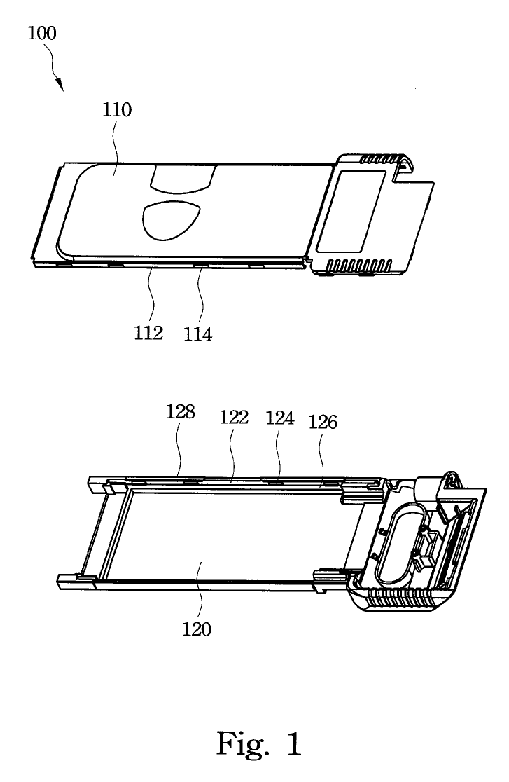

Refer to FIG. 1. FIG. 1 illustrates an explosion diagram of an embodiment of a wireless network card using a wireless network card covering structure of the invention. The wireless network card 100 includes an upper metal cover 110 and a lower metal cover 120. The wireless network card covering structure includes a contact structure and a coupling structure. The coupling structure couples the upper metal cover 110 and the lower metal cover 120 of the wireless network card 100. The contact structure keeps the upper metal cover 110 in contact with the lower metal cover 120 to maintain an electromagnetic susceptibility (EMS) of the wireless network card 100.

The upper metal cover 110 has a plurality of upper metal cover walls 112 raised from a surface facing the lower metal cover 120 of the upper metal cover 110. The lower metal cover 120 has a plurality of lower metal cover walls 122 raised from a surface facing the upper metal cover 110 of the lower metal cover 120. The wireless network card covering structure may take the upper metal cover walls 112 and the lower metal cover walls 122 as the contact structure. The upper metal cover walls 112 may touch the lower metal cover wall 122 to maintain the EMS of the wireless network card 100 when the upper metal cover 110 couples with the lower metal cover 120. The contact structure may further include a wall flange 128 disposed on the lower metal cover wall 122 and the wall flange 128 is raised from the lower metal cover wall 128 to secure the connection between the upper metal cover wall 112 and the lower metal cover wall 122.

The upper metal cover 110 has a plurality of openings 114 disposed on the upper metal cover walls 112. The lower metal cover 120 has a plurality of plastic protrusions 124. The plastic protrusions 124 are disposed on the lower metal cover walls 122 and correspond to the openings 114. The wireless network card covering structure may take the plastic protrusions 124 and the openings 114 as the coupling structure to couple the upper metal cover 110 and the lower metal cover 120. The upper metal cover 110 may couple with the lower metal cover 120 by coupling the plastic protrusions 124 and the openings 114 when inserting the upper metal cover 110 into the lower metal cover 120. The number of the openings 114 may be the same as the number of the plastic protrusions 124.

The plastic protrusions 124 may be formed on the lower metal cover walls 122 by an insert molding method. The plastic protrusions 124 may be formed on an inner side of the lower metal cover walls 122. Thus the plastic protrusions 124 are hidden in the wireless network card 100 when the plastic protrusions 124 couple with the openings 114. Each lower metal cover wall 122 may further include a base 126 disposed below the plastic protrusions 124. The base 126 may extend more than the plastic protrusions 124. The upper metal cover walls 112 may touch the bases 126 to position the upper metal cover 110 and the lower metal cover 120.

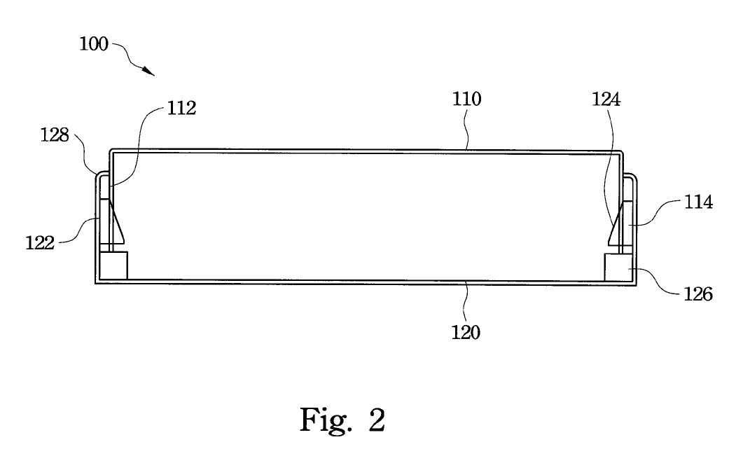

Refer to FIG. 2. FIG. 2 illustrates sectional diagram of the embodiment of the wireless network card in FIG. 1. The shape of the plastic protrusions 124 may be a trapezoid with wider bottom to smoothly couple the openings 114 with the trapezoid plastic protrusions 124 and prevent the plastic protrusions 124 from departing from the openings. The upper metal cover walls 112 may contact the lower metal cover walls 122 directly. The upper metal cover walls 112 may contact the lower metal cover walls 122 by the wall flanges 128 to secure the contact between the upper metal cover 110 and the lower metal cover 120 for maintaining the electromagnetic susceptibility of the wireless network card 100. The upper metal cover 110 may touch the bases 126 of the lower metal cover 120 to position the upper metal cover 110 and the lower metal cover 120 during the assembly of the wireless network card 100.

The coupling structure and the contact structure of the wireless network card covering structure are formed individually, thus the molding precision and a yield of the wireless network card may be significantly increased. The upper metal cover may couple with the lower metal cover by coupling the plastic protrusions and the openings when inserting the upper metal cover into the lower metal cover.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A wireless network card covering structure for coupling an upper metal cover and a lower metal cover comprising:
a contact structure comprising a plurality of upper metal cover walls disposed on the upper metal cover and a plurality of lower metal cover walls disposed on the lower metal cover, wherein the upper metal cover walls touch the lower metal cover walls to maintain an electromagnetic susceptibility of a wireless network card; and
a coupling structure comprising a plurality of openings and a plurality of plastic protrusions, the openings and the protrusions are disposed on the upper metal cover walls and the lower metal cover walls respectively, wherein the plastic protrusions are coupled with the openings for coupling the upper metal cover and the lower metal cover.

2. The wireless network card covering structure of claim 1, wherein the plastic protrusions are disposed on the lower metal cover walls, the openings are disposed on the upper metal cover walls to couple with the plastic protrusions.

3. The wireless network card covering structure of claim 2, wherein the contact structure further comprises at least one wall flange disposed on the lower metal cover walls, wherein each wall flange is raised from the lower metal cover wall and touches the upper metal cover walls to secure the connection between the upper metal cover walls and the lower metal cover walls.

4. The wireless network card covering structure of claim 2, wherein each lower metal cover wall has an inner side, the plastic protrusions are disposed on the inner walls of the lower metal cover walls.

5. The wireless network card covering structure of claim 4, wherein each lower metal cover wall has a base placed below the plastic protrusions, the upper metal cover walls touch the bases to position the upper metal cover and the lower metal cover.

6. The wireless network card covering structure of claim 5, wherein the bases extend more than the plastic protrusions.

7. The wireless network card covering structure of claim 1, wherein a number of the plastic protrusions is the same as a number of the plastic protrusions

8. A wireless network card structure comprising:
a lower metal cover comprising:
a plurality of lower metal cover walls, and
a plurality of plastic protrusions disposed on the lower metal cover walls; and
an upper metal cover comprising:
a plurality of upper metal cover walls, and
a plurality of openings disposed on the upper metal cover walls and corresponding to the plastic protrusions, wherein the upper metal cover walls touch the lower metal cover walls and the openings are coupled with the plastic protrusions to couple the upper metal cover and the lower metal cover.

9. The wireless network card structure of claim 8, wherein each lower metal cover wall has an inner side, the plastic protrusions are disposed on the inner walls of the lower metal cover walls.

10. The wireless network card structure of claim 8, wherein the upper metal cover walls touch the lower metal cover walls.

11. The wireless network card structure of claim 10, wherein each lower metal cover wall further comprises at least one wall flange, each wall flange is raised from the lower metal cover wall and is contact with the upper metal cover walls to secure the upper metal cover walls contact the lower metal cover walls.

12. The wireless network card structure of claim 8, wherein a number of the plastic protrusions is the same as a number of the plastic protrusions.

13. The wireless network card structure of claim 8, wherein each lower metal cover wall has a base placed below the plastic protrusions, the upper metal cover walls touch the bases to position the upper metal cover and the lower metal cover.

14. The wireless network card structure of claim 8, wherein the bases extend more than the plastic protrusions.
